(19) United States
(12) Patent Application Publication
(10) Pub. No.: US 2015/0349191 A1
(43) Pub. Date: Dec. 3, 2015

(54) METHOD FOR PRODUCING A THICK CRYSTALLINE LAYER

(71) Applicant: COMMISSARIAT A L'ENERGIE ATOMIQUE ET AUX ENERGIES ALTERNATIVES, Paris (FR)

(72) Inventors: Hubert MORICEAU, SAINT-EGREVE (FR); Christophe MORALES, St. Pierre de Mesage (FR); Frank FOURNEL, VILLARD-BONNOT (FR)

(21) Appl. No.: 14/654,678

(22) PCT Filed: Dec. 17, 2013
(86) PCT No.: PCT/FR2013/053146

§ 371 Date: Jun. 22, 2015

(30) Foreign Application Priority Data
Dec. 21, 2012 (FR) 1262736

(51) Int. Cl. H01L 31/18; H01L 31/028

(52) U.S. Cl. CPC H01L 31/1812; H01L 31/1872; H01L 31/1864; H01L 31/028

(57) ABSTRACT

The process wherein steps consisting in: a) implanting ionic species through a substrate with at least on its surface, a crystalline layer of SiₓGe₁₋ₓ, so as to form a weakened plane in said layer, bounding a seed film; b) depositing an amorphous layer of Si_{y}Ge_{1-y} on the seed film; c) applying a splitting process so as to obtain a detached structure comprising the seed film and the amorphous Si_{y}Ge_{1-y} layer on the one hand, and a negative of the substrate on the other hand; and d) applying, to the detached structure, a heat treatment so as to obtain a thick crystalline layer with a thickness larger than 10 microns, which layer is not secured to the negative. The invention also relates to a structure wherein a crystalline silicon substrate wherein a seed film and amorphous silicon layer containing a stressed region comprising implanted ions.

The present invention relates to a method for producing a thick crystalline layer such as a layer of Si, Ge or a SiGe alloy, in particular dedicated to photovoltaic applications. According to another aspect, the present invention relates to an initial structure which may originate from an intermediate step of the method according to the invention and according to another aspect, the present invention relates to a detached structure which may originate from another intermediate step of the method according to the invention.

Photovoltaic applications require using crystalline substrates of silicon, germanium or SiGe alloy sufficiently thick so that the photonic efficiency is optimal, but also sufficiently thin so that the cost of the material is not too high. A substrate thickness of around a few dozen micrometers, such as a thickness between 20 and 50 micrometers is suitable.

Producing this type of substrate may be obtained from silicon or germanium ingots or even thick epitaxial layers on host substrates but the ingot cutting for forming each of the substrates implies a loss of material from the cutting (thickness of the saw cut) and preparing the surface of the substrates (thinning by lapping, chemical attack, polishing). In total, producing a silicon substrate having a thickness of 20 to 50 μm, leads to losing around a hundred micrometers of crystalline silicon from the ingot. This loss of material represents an appreciable part of the cost of each substrate.

Currently, other techniques of producing such substrates involve deep implantations (at several dozens of micrometers in depth) of gaseous ions (hydrogen, helium, . . . ) alone or combined with thermal treatments allowing a fracture at the implanted area in such a manner as to form substrates of a few dozen micrometers. The drawback of this approach is that it is based on using implantation equipment capable of providing energies of the order of a few MeV. These equipments are expensive, not available commercially such that an approach with such equipments remains difficult for a high-volume manufacture with a view to applications in the field of photovoltaics.

Other techniques based on silicon metallurgy (tapping, direct forming . . . ) have been developed in order to manufacture silicon substrates of a few dozen (or even hundred) micrometers in thickness. However, these forming techniques are also tricky to implement for high-volume manufacturing such as is expected in the case of photovoltaic applications.

One of the purposes of the invention is to overcome one or several of these drawbacks. To this end, and according to a first aspect, the present invention proposes a method for producing a thick crystalline layer, in particular intended for photovoltaic applications, comprising the steps consisting in

a) Implanting ionic species through a surface of a substrate including at least on the surface a crystalline layer of SiₓGe₁₋ₓ with 0≦x≦1 in such a manner as to form a weakened plane in said layer delimiting a seed film under the surface of the substrate,

b) Depositing an amorphous layer of Si_{y}Ge_{1-y} with 0≦x≦1 and y equal to or different from x on the seed film leading to the formation of a weakened composite structure,

c) Applying a fracture treatment in such a manner as to cause a fracture of the substrate according to the weakened plane and obtain a detached structure including the seed film and the amorphous layer of Si_{y}Ge_{1-y} on the one hand, and a negative (4) of the substrate (1) on the other hand, and

d) Applying to the detached structure a thermal treatment for bringing about the crystallization of the amorphous layer of Si_{y}Ge_{1-y} from the seed film, in such a manner as to obtain a thick crystalline layer (9) of a thickness higher than 10 micrometers and separate from the negative (4)

In the present document the expression “thick layer” means a layer having a thickness of at least a dozen micrometers, for example a thickness between 10 and 50 micrometers. In the present document, the terminology “amorphous layer” means a layer of a material of which the crystalline structure is mainly without order at long distance. In the present document, the term “weakened plane” means, the area impacted by the ion implantation and in which the fracture occurs.

Advantageously x is equal to y in such a manner as to keep the same lattice constant and prevent generating crystallographic defects during the crystallization of the amorphous layer.

When x and y are different, it is worth noting that the closer x and y are, the less the crystallographic defects generated during the crystallization of the amorphous layer.

Thus, the present invention allows producing a thick crystalline layer by using steps which do not lead to a great loss of used crystalline material, easily reproducible and suitable for large volume manufacture. In fact, the implantation step is carried out with a relatively low depth, it may hence be carried out with equipment with low implantation energy (around 250 keV), available commercially, in such a manner that the costs of this step are reasonable. Furthermore, the deposition of an amorphous layer of Si_{y}Ge_{1-y} may be accomplished at a low cost and at a speed which is compatible with a high volume manufacture. Moreover, the thermal treatment may be operated by using standard heating equipments at temperatures below 1250° C., preferentially within the range of 300 to 1200° C., suitable for a manufacture of large volumes at a low cost. Furthermore, after the step c), the negative of the implanted substrate remaining after the separation of the detached structure may be recycled in order to become a new substrate based on which the method of the present invention may be reproduced. This participates in a low production cost.

Advantageously, the step of depositing the layer of amorphous SiyGe1_{-y} is carried out until obtaining a thickness between 10 micrometers and 50 micrometers.

According to a disposition, the step of implanting ionic species is carried out with hydrogen and/or helium based ions with an energy between a few keV and 250 keV and a dose between 10¹⁶ and a few 10¹⁷ at/cm². Thus, thanks to the use of a seed layer that is not thick, the depth of the implantation is low and the costs of this step remain reasonable.

Preferably, the method comprises a step i) of balancing inner stresses generated in the weakened composite structure during step c) of applying a fracture treatment, in such a manner as to prevent deformations of the weakened structure which can decrease the quality of the fracture and crystallization. The risks of damaging the layers are hence reduced and the appearance of macroscopic defects is reduced. The fracture may occur without risk of sudden change of mechanical energy able to cause the break of the negative or the weakened composite structure.

Preferably, the layer of amorphous Si_{y}Ge_{1-y} is deposited in such a manner as to hardly be or not be stressed. In the opposite case, the stress is taken into account in step i) for the balancing the stresses.

According to a disposition, the step i) of balancing inner stresses includes the application of a pressure along two opposite directions on either side and perpendicularly to the weakened composite structure during the application of a fracture treatment according to the step c).

Advantageously, the application of pressure is carried out by two pistons with a pressure higher than 1000 daN/m². Thus, the applied pressure is homogenous over the entire structure and the deformation of the structure is limited. This in particular restricts the risks of damage linked to a sudden change in the mechanical energy during the fracture.

According to another possibility, the step i) of balancing inner stresses includes an implantation of ionic species in the layer of amorphous SiyGe1_{-y}, in particular an implantation of silicon or germanium or other ionic species, in such a manner as to create a region of stress.

In fact, the introduction of ionic species in the amorphous layer allows creating a layer in compression reducing the deformation risks during fracture. In fact, the prior implantation of the ionic species at step a) generates a stress in the crystalline SiₓGe1-x which would lead to the deformation during fracture if this stress was not compensated by an implantation in the layer of amorphous Si_{y}Ge1-y. Furthermore, the use of ions of the same nature as the substrate (silicon for a silicon substrate for example) is particularly appropriate as it does not disrupt the nature of the obtained layer. Ions may be implanted with a small depth in the layer of SiyGe1-y in such a manner that the implantation only requires low energy in such a manner that it remains cheap. Moreover, it is not necessary to implant an important dose as the purpose is not to create a weakened plane.

The implantation of ionic species according to the step i) is preferably carried out prior to the fracture treatment of step c).

According to a disposition, the step i) includes an implantation of boron or phosphorous based ionic species. These ions may advantageously serve as dope to the detached structure for example a doping of type P with the boron (B) and a doping of type N with the phosphorous (P).

According to a disposition, the step of implanting ionic species in the layer of amorphous SiyGe1-y is carried out with an energy between 80 keV and 120 keV and a dose between 4·10¹⁴ and 6·10¹⁵ Si/cm².

According to yet another possibility, the step i) of balancing inner stresses includes a deposition of a layer stressed into compression on the layer of amorphous SiyGe1-y, in particular a layer of amorphous SiyGe1-y, or a layer of silicon oxide. This type of deposition is obtained by increasing the speed of deposition of this amorphous SiyGe1-y or silicon oxide, for example by increasing the strength of the deposition, which incorporates within the film part of the carrier gas with in particular hydrogen and argon. The fact of depositing a layer stressed into compression allows balancing, during the fracture step c), the stresses in compression linked to the presence of the ionic species implanted beforehand in the substrate and minimizing or even cancelling the global deformation of the weakened composite structure. Moreover, the stressed layer is compatible with the layer of amorphous SiyGe1-y as it is constituted of the same material or of a material comprising silicon. When the stressed layer is made of amorphous SiyGe1-y, it may thus be part of the layer of amorphous SiyGe1-y, which was deposited beforehand.

The deposition of the layer stressed into compression according to the step i) is preferably carried out prior to the fracture treatment of step c).

Concretely, step c) of applying a fracture treatment includes the application of a thermal fracture treatment, in particular at at least a temperature between room temperature and 600° C., and/or the application of a mechanical fracture treatment according to the weakened plane, such as the application of a flexion, a traction, a lateral insertion of a blade, of a shearing stress, a water jet or an air blast. Thus, the thermal treatment may be completed by a mechanical treatment thus allowing to reduce the thermal budget to be applied for obtaining a fracture. Thus, the deformations in the weakened composite structure, exacerbated by the rise in temperature, are reduced at the moment of fracture. In fact, the stressed layers have different dilation coefficients from that of the amorphous SiyGe1-y, hence a high temperature induces important stresses.

Advantageously, the thermal treatment applied to step c) is carried out in a range between 200 and 500° C. and preferably a range between 250 and 360° C. Thus, the temperature of fracture remains low, thus being favorable for reducing deformations in the structure.

Preferably, step c) of applying the thermal fracture treatment is achieved by applying temperature steps. It is thus possible to avoid too sudden changes of the inner stresses.

Advantageously, the method comprises prior to carrying out all or part of step b) of depositing the layer of amorphous SiyGe1-y, the application of a thermal pre-treatment. This thermal pretreatment allows the partial maturation of the cavities formed by the implantation of step a). It is hence possible to reduce the intensity of the fracture treatment, for example to reduce the thermal budget (time, temperature pair) used for obtaining the fracture at step c). This allows reducing the deformation of the weakened composite structure during fracture.

According to a disposition the step d) of thermal crystallization treatment comprises the application of a temperature within a range of 400° C. and 1200° C. during, a period of time between a few hours and a few days. Thus, the crystallization of the layer of amorphous Si_{y}Ge_{1-y} starts from the crystalline imprint of the seed film of crystalline SixGe1-x and propagates in the amorphous layer in order to obtain at the end a thick layer of good crystalline quality.

According to a variant, the step c) of applying a fracture treatment and step d) of applying a thermal crystallization treatment are achieved by a unique thermal treatment ranging between room temperature to 1200° C. by applying temperature steps. This reduces the cycle time of the method and prevents handling the structure between the two steps c) and d) which may be carried out in the same equipment.

In an advantageous manner, the method comprises prior to step d) of applying the thermal crystallization treatment, a step ii) including a deposition of at least one film of amorphous material on the exposed surface of the layer of amorphous SiyGe1-y. The presence of this film of amorphous material, which does not have a crystalline structure and being from a material different from SiyGe1-y, prevents the start of crystallization from the exposed face of the layer of amorphous SiyGe1-y and promotes a start of crystallization from the seed film of crystalline SixGe1-x only. It is understood that for being able to ensure its function, this film of amorphous material is constituted of a material other than SiyGe1-y. In the present document, the expression “exposed face of the layer of amorphous SiyGe1-y” means the face of the layer of amorphous SiyGe1-y which is opposite the one in contact with the seed film.

According to a possibility, the film of amorphous material is deposited prior to the fracture treatment.

Preferably, step ii) including a deposit of at least a film of amorphous material on the surface of the layer of amorphous SiyGe1-y also includes a step of depositing at least a film of the same amorphous material on the free surface of the seed film. The presence of a film of amorphous material on the side of the seed film of the detached structure allows balancing the stresses generated by the presence of the film on the layer of amorphous SiyGe1-y appearing during the thermal crystallization treatment.

In an advantageous manner, the films of amorphous material are achieved in silicon oxide, of general formula SiOₓ with 0≦x≦2. Thus the deposited material has a material different from that of the layer of amorphous SiyGe1-y while remaining compatible with the later treatments of the amorphous layer, for example during step d).

According to a possibility, the step including the deposition of at least a film of an amorphous material comprises the deposition of at least another film of different nature in such a manner as to create a stacking of several films.

Advantageously, the method comprises prior to step d) of applying the thermal crystallization treatment, a step iii) of additional thermal degassing treatment of the layer of amorphous SiyGe1-y. Thus, it is possible to remove all or part of the gaseous elements, for example hydrogen, incorporated in the layer of amorphous SiyGe1-y when it is being deposited. This prevents the appearance of harmful effects linked to the presence of hydrogen gas during the thermal crystallization treatment, such as exfoliations or bubbling of amorphous SiyGe1-y.

Preferably, the additional thermal treatment iii) is carried out in a range of temperatures between 350° C. and 500° C.

According to a variant, the method comprises, prior to the implantation step a), a step of depositing a lower portion of the layer of amorphous SiyGe1−y and comprises, after the step a), a step of cleaning the implanted surface of said lower portion, the step b) consisting in depositing an upper portion of the layer of amorphous SiyGe1-y.

Preferably, the accumulated lower and upper portions form the totality of the layer of amorphous SiyGe1-y.

The cleaning of the surface, achieved after the implantation step a), advantageously allows removing any contamination or any oxide on the surface in order to optimize the later depositions, for example optionally that of the upper portion of said amorphous layer, and improve the crystallization according to the step d). A cleaning may be in particular be carried out for removing the organic contaminants (for example, by a sulphuric acid, ozone based solution . . . ), for removing particles (for example, by an ammonia based solution . . . ), for removing metal contaminants (for example, by a hydrochloric acid based solution) for removing oxide (for example, by etching in a solution of hydrofluoric acid), leaving a surface of the lower portion of the layer of amorphous SiyGe1-y capable for the deposition of the upper portion of the layer of amorphous SiyGe1-y and for the generation of a crystallization during the step d).

According to a particular disposition, x is equal to 1 and y is equal to 1 in such a manner that the substrate comprises at least on the surface a crystalline layer of silicon and that the step b) comprises the deposition of a layer of amorphous silicon on the seed film.

Preferably, the layer of SixGe1-x is single-crystal in such a manner that the seed film is formed of a single-crystal material. This allows the crystallization of the amorphous layer into a single-crystal material following step d).

In the present document it is obvious that the crystallization according to the invention allows obtaining a single-crystal material and not a polycrystalline material comprising for example large grains of crystals.

According to a second aspect, the invention proposes a weakened composite structure comprising from its base to its surface, a substrate comprising at least on its surface a layer of crystalline SiXGe1-x having a weakened plane delimiting a seed film having a thickness between around 10 nanometers and 2 micrometers, a layer of amorphous SiyGe1-y having a thickness higher than 10 micrometers on the seed film, the layer of amorphous SiyGe1_{-y} including a region of stress comprising implanted ionic species.

This weakened structure is thus suitable for applying the fracture treatment according to step c) and the thermal crystallization treatment according to step d). In fact, the presence of these ionic species in the superficial layer of amorphous SiyGe1-y allows partially or totally balancing the stresses generated by the ionic species implanted in the substrate, during step a), and contributes in maintaining a structure without any great deformation.

Preferably, the SixGe1-x is single-crystal as well as the seed film in such a manner as to obtain in the end a thick single-crystal layer.

According to a third aspect, the invention proposes a detached structure comprising from its base to its surface, a film of amorphous material of silicon oxide having a thickness of a few dozen nanometers, a seed film of crystalline SiXGe1-x having a thickness between around 10 nanometers and 2 micrometers on the film of amorphous material, a layer of amorphous SiyGe1-y having a thickness higher than 10 micrometers on the seed film and a film of amorphous material of silicon oxide having a thickness of a few dozen nanometers on the layer of amorphous SiyGe1-y. The presence of the two films of amorphous material in silicon oxide advantageously allows balancing the stresses on either side of the seed film and the layer of amorphous SiyGe1-y in such a manner as to prevent a large deformation for example during the application of the thermal crystallization treatment. The film deposited on the layer of amorphous SiyGe1-y further contributes in preventing an initiation of the crystallization from the upper surface of the layer of amorphous SiyGe1-y.

Preferably still, the seed film of SixGe1-x is single-crystal.

Other aspects, purposes and advantages of the present invention will become more apparent upon reading the following description of the different variants of the latter, given by way of non limiting examples and made with reference to the accompanying drawings. The figures do not necessarily respect the scale of all the represented elements in such a manner as to make them readable. The dotted lines symbolize a weakened plane. In the rest of the description, for the sake of simplicity, identical, similar or equivalent elements of the different embodiments bear the same numerical references.

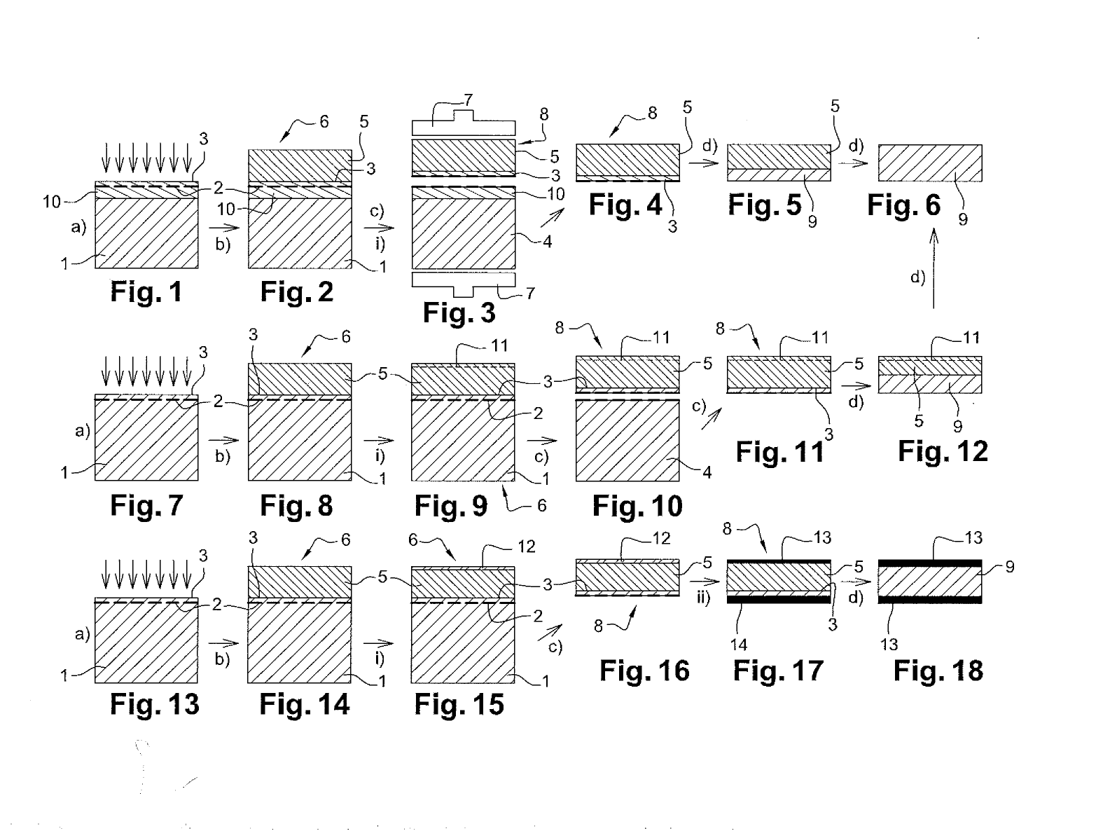

FIGS. 1 to 6 represent an embodiment of the method according to the invention.

FIGS. 7 to 12 represent a variant of the method according to the invention.

FIGS. 13 to 18 represent yet another variant of the method according to the invention.

FIG. 1 illustrates a substrate 1 including at least on the surface a crystalline layer and preferably a single-crystal layer 10 of silicon within which an implantation of ionic species according to the step a) of the method is achieved (in this case x=1). The used ionic species are for example hydrogen based ions and are implanted with an energy between a few keV and 250 keV with a dose between 10¹⁶ to a few 10¹⁷ at/cm². According to another possibility, the implantation step a) is achieved with helium ions and according to yet another possibility, the step a) consists in a co-implantation of hydrogen and helium ions. This implantation step a) leads to the formation of a weakened plane 2 comprising microcavities and delimiting on either side a seed film 3 of single-crystal silicon and a negative 4 of the substrate 1.

According to a non illustrated variant, it is possible to deposit a protective layer prior to the implantation step a), in amorphous silicon for example, on the surface of the single-crystal layer 10 of silicon on the surface of the substrate 1 in order to protect the surface from contaminations which may take place during implantation or for preventing a damaging of the single-crystal layer. This protective amorphous layer may have a thickness of a few dozen micrometers. It is obvious that the energy for implanting ionic species is determined by taking into account this thickness in order to attain the required depth of the weakened plane 2 in the single-crystal silicon 10 layer. A required thickness of the seed film 3 is at least 10 nanometers. Preferably, this thickness is at least 100 nanometers so as to slightly shift the implantation peak in the layer 10 of silicon on the surface of the substrate 1 and thus keep the single-crystal quality on the surface for the future seed film 3. Furthermore, this protective layer being in amorphous material, it is not or is hardly damaged by the implantation. This protective layer may hence be kept in order to carry out the step b) of depositing a layer of amorphous silicon 5 on the seed film 3.

In a visible manner on FIG. 2 after the implantation step a), the surface of the substrate 1 or the protective layer in amorphous silicon is prepared in such a manner as to particularly remove any contamination or any oxide on the surface before proceeding with the step b). For example a cleaning is carried out for removing organic contaminants (for example by a sulphuric acid, ozone based solution . . . ), for removing particles (for example, by an ammonia based solution . . . ), for removing metal contaminants (for example, by a hydrochloric acid based solution) for removing oxide (for example, by etching in a solution of hydrofluoric acid), leaving a surface of silicon capable for the deposition of the amorphous silicon layer 5 and the generation of a crystallization during the step d). It is possible to use other cleaning techniques for example by ionic pickling or by introducing a step of silanisation of the surface.

As illustrated on FIG. 2, a layer of amorphous silicon 5 is then deposited on the seed film 3 according to the step b) up to a thickness between around 15 and 30 micrometers depending on the required applications. The deposition may be carried out by different techniques, such as PECVD (Plasma Enhanced Chemical Vapor Deposition) or PVD (Physical Vapor Deposition) and leads to the formation of a weakened composite structure 6.

As illustrated on FIG. 3, a fracture treatment is achieved by thermal treatment applied for example at 400° C. during 1 h according to step c) of the method. The rise in temperature increasing the inner stresses of the weakened composite structure 6 leading to the deformation of the structure 6, a step i) suitable for balancing the effects of these stresses is carried out at the same time as the thermal treatment. This step of balancing the stresses is carried out by exerting a mechanical pressure on each of the main surfaces of the weakened structure 6, in particular by the pistons 7 exerting a pressure higher than around 1000 daN/m².

As illustrated on FIG. 4, once the weakened substrate 1 fractured according to the weakened plane 2, the detached structure 8 is recovered in order to carry out the crystallization of the layer of amorphous silicon 5 into single-crystal silicon. The sole purpose of the dashes represented on the exposed face of the thin film 3 is to illustrate the prior presence of the weakened plane. Furthermore, according to a non illustrated disposition, the negative 4 of the substrate 1 may be recycled in order to be reused for producing a new thick layer of single-crystal silicon 9.

As illustrated on FIG. 5, a thermal crystallization treatment according to the step d) of the method is applied to the detached structure 8 at a temperature of around 470° C. during several days. The layer of amorphous silicon 5 gradually crystallizes from the seed film 3 which transmits its crystalline imprint. By way of example, 12 days are needed for crystallizing the amorphous layer 5 of 15 μm of silicon at 500° C. and 5 days for this same thickness at 520° C. Finally, the thermal crystallization treatment is ended by applying a temperature of 1200° C. during a few hours (FIG. 6) allowing the formation of a thick layer 9 of single-crystal silicon including the same symmetry as that of the seed film 3 and satisfying for example the needs of the photovoltaic applications. This very high temperature also allows reducing the number of crystalline defects.

According to a variant, the thermal crystallization treatments are carried out by applying a temperature gradient so that the advance of the crystallization front be preferentially from the seed film 3 towards the surface of amorphous layer 5.

FIGS. 7 to 12 illustrate a variant of the method according to the invention. FIG. 7 represents a substrate 1 entirely constituted of a crystalline layer of silicon and preferably of a single-crystal layer 10 of silicon in which hydrogen ions are implanted with an energy of 100 keV and a dose of 10¹⁷ at/cm² in such a manner as to form a weakening plane 2 delimiting a seed film 3 of single-crystal silicon. According to a non illustrated possibility, the surface of the substrate 1 of silicon is covered beforehand by a protective layer of amorphous silicon oxide SiO² having a thickness of 10 nm. This protective layer advantageously allows protecting the surface of single-crystal silicon during the implantation of the ionic species. After implantation, this layer is cleaned by standard chemical treatment, such as a treatment in a solution containing sulphuric acid for removing hydrocarbons. A treatment in a solution of Ammonium Peroxide Mixture type or APM is then applied in such a manner as to generate a new proper chemical silicon oxide protecting the surface of the single-crystal layer 10 of silicon and which is removed by a treatment with hydrofluoric acid HF for exposing the seed film 3 of single-crystal silicon right before carrying out the step b) of depositing the layer of amorphous silicon 5, such as illustrated on FIG. 8, over a thickness of around 25 micrometers.

As illustrated on FIG. 9, a step i), of balancing stresses generated in the weakened composite structure 6 by the implantation of hydrogen followed by the application of the thermal fracture treatment, is carried out by implanting silicon under the surface of the layer of amorphous silicon 5 with a dose of around 5·10¹⁴ Si/cm² and an energy of around 100 keV. These silicon ions in fact allow generating a region of stress 11 localized in the layer of amorphous silicon 5 providing a stress of the same nature as that generated in the substrate 1 during the thermal treatment. Furthermore, the species implanted during the step i) being in silicon, it does not denature the layer of amorphous silicon 5.

As illustrated on FIG. 10, the fracture treatment is carried out by a thermal treatment at around 320° C. during 20 h without generating any important deformation in the weakened composite structure 6 in such a manner that the sudden changes of energy appearing in the structure 6 during the fracture are limited.

According to a non illustrated variant, the fracture treatment is obtained by applying a thermal treatment at a temperature lower than 320° C. and is completed by an application of a mechanical stress, such as the application of a blade at the weakened plane 2 in the substrate 1, a water jet or an air blast or a shearing stress. Furthermore, the thermal fracture treatment may be carried out at a temperature a little higher than 320° C. and over a reduced duration. Applying a mechanical stress thus completes this thermal budget (duration temperature) with a view to obtaining the fracture.

As illustrated on FIG. 11, the detached structure 8 comprising the seed film 3 and the layer of amorphous silicon 5 is subjected to the thermal crystallization treatment in such a manner that the amorphous silicon crystallizes from the single-crystal seed film 3 (FIG. 12). A thick layer 9 of single-crystal silicon is thus obtained.

FIGS. 13 to 18 illustrate another variant of the method according to the invention.

FIG. 13 illustrates the step a) of implantation in the substrate 1 entirely constituted of the crystalline silicon layer and preferably of the single-crystal silicon layer 10.

FIG. 14 illustrates the step b) of depositing the layer of amorphous silicon 5 on the seed film 3.

FIG. 15 illustrates the step i) of balancing inner stresses of the weakened structure 6 by applying a layer stressed into compression 12 of amorphous silicon on the layer of amorphous silicon 5 in such a manner as to compensate the effects of the stress generated by the hydrogen ions implanted in the substrate 1 and thus limit the global deformation of the structure 6.

Then, as illustrated on FIG. 16, a fracture treatment is applied to the weakened structure 6 by applying a thermal treatment carried out with several temperature steps. The temperature is first applied at around 320° C. during several hours, then it is taken up to 340° C. and finally to 360° C. in such a manner as to limit the duration of application of the highest temperature, limit the deformations and risks of breaking the structure 6 and/or the negative 4 during the fracture.

As illustrated on FIG. 17, the layer stressed into compression 12 is removed from the surface by a chemical treatment for example with a potash based solution. Then a film of amorphous material 13, of a nature different from silicon, such as amorphous silicon oxide is deposited on the surface of the amorphous silicon layer 5 according to the step ii) of the method. This film 13 is for example deposited at 350° C. by PECVD until obtaining a thickness of 100 nm. It may be deposited by other techniques of deposition at other temperatures. This film 13 has for effect to promote a crystallization of the amorphous silicon from a seed film 3 rather than from the exposed surface of amorphous silicon in the absence of this film of amorphous material 13. This method allows in particular preventing the presence of two different crystallization sites generating defects at the meeting point of the two crystallization fronts. According to a variant, the film of amorphous material 13 may be deposited on the layer of amorphous silicon 5 prior to applying the fracture treatment. Furthermore, this amorphous film 13 may be constituted of a stacking of films of different nature.

Nevertheless, this film of amorphous material 13 may generate stresses in the detached structure 8 during the thermal crystallization treatment. A second film of the same thickness and same nature 14 is hence advantageously deposited on the exposed face of the seed film 3 after fracture. Thus, the generated stresses are symmetrical thereby limiting the appearance of deformations in the detached structure 8 (FIG. 17) during the thermal crystallization treatment.

As illustrated on FIG. 18, the application of the thermal crystallization treatment according to step d) allows crystallizing the layer of amorphous silicon 5 and forming a thick layer of single-crystal silicon 9 suitable for photovoltaic applications.

According to a non illustrated variant, an additional thermal treatment according to step iii) of the method is applied to the detached structure 8 prior to applying the thermal crystallization treatment. This additional treatment allows degassing the layer of amorphous silicon 5 for example hydrogen included in the layer during the deposition thereof. This thermal treatment may be carried out at temperatures lower than 600° C. and preferably between around 350° C. and 500° C. in such a manner that the degassing does not lead to exfoliations or bubbling of the silicon of the amorphous layer 5. Furthermore, the hydrogen exodiffusion carried out by this additional thermal treatment may modify the stresses in the seed film 3 of single-crystal silicon of the detached structure 8. Additional means (mechanical means, modification of the natures and thicknesses of the film depositions of amorphous material 13) for preventing the deformation of the structure 8 may hence be used according to the initial concentration of hydrogen present in the layer of amorphous silicon 5.

By way of example, for a layer of amorphous silicon 5 of 20 μm, the degassing may be obtained by a thermal treatment at 470° during 20 days.

According to yet another non illustrated variant, a thermal pretreatment is applied before or during the step b) of depositing the layer of amorphous silicon 5. Typically the thermal pretreatment is carried out at 320° C. during 1 h. This allows the maturation of the crystalline defects formed by the ionic implantation in such a manner that a low fracture thermal budget, such as 12 hours at 320° C., is then necessary in order to obtain the fracture after the deposition of the layer of amorphous silicon 5.

The examples given above are described in reference to silicon but all these examples may be suitable for the materials of type SiₓGe₁₋ₓ with 13)(1 in particular for the seed film 3 and Si_{y}Ge_{1-y} for the amorphous layer 5. In the case where y is equal to 0, the amorphous layer 5 of germanium is advantageously deposited by PECVD from a phase of germane, within a temperature range between around 100° C. and 300° C., and preferably at a temperature lower than 150° C. in order to prevent beginnings of crystallization during the deposition thereof. The crystallization of the layer of germanium 5 is obtained by applying a thermal treatment at around 600° C. under nitrogen for a duration of 10 hours for a thickness of 25 micrometers.

Thus, the present invention proposes a method for producing a thick crystalline layer and preferably a single-crystal layer 9 which is simple to implement, cheap and reproducible.

It goes without saying that the invention is not limited to the variants described above by way of examples but comprises all the technical equivalents and variants of the described means as well as their combinations.

1. A method for producing a thick crystalline layer, in particular intended for photovoltaic applications, comprising the steps of:
a) Implanting ionic species through a surface of a substrate including at least on a surface a crystalline layer of SiₓGe₁₋ₓ with 0≦x≦1 in such a manner as to form a weakened plane in said crystalline layer delimiting a seed film under the surface of the substrate,
b) Depositing a layer of amorphous Si_{y}Ge1_{-y} with 0≦y≦1 and y equal to or different from x on the seed film leading to the formation of a weakened composite structured,
c) Applying a fracture treatment in such a manner as to cause a fracture of the substrate according to the weakened plane and obtain a detached structure including the seed film and the layer of amorphous Si_{y}Ge_{1-y} on the one hand, and a negative of the substrate on the other hand, and
d) Applying to the detached structure a thermal treatment for bringing about the crystallization of the layer of amorphous Si_{y}Ge_{1-y} from the seed film, in such a manner as to obtain the thick crystalline layer of a thickness higher than 10 micrometers and separate from the negative.

2. The method of producing according to claim 1, wherein the method comprises a step i) of balancing inner stresses generated in the weakened composite structure during step c) of applying a fracture treatment.

3. The method of producing according to claim 2, wherein the step i) of balancing inner stresses includes the application of a pressure along two opposite directions on either side and perpendicularly to the weakened composite structure during the application of a fracture treatment according to the step c).

4. The method of producing according to claim 3, wherein the application of pressure is carried out by two pistons with a pressure higher than 1000 daN/m².

5. The method of producing according to claim 2, wherein the step i) of balancing inner stresses includes an implantation of ionic species in the layer of amorphous Si_{y}Ge_{1-y}, in such a manner as to create a region of stress.

6. The method of producing according to claim 2, wherein the step i) of balancing inner stresses includes a deposition of a layer stressed into compression on the layer of amorphous Si_{y}Ge_{1-y}.

7. The method of producing according to claim 1, wherein the step c) of applying a fracture treatment includes an application of a thermal fracture treatment, and/or an application of a mechanical fracture treatment onto the weakened plane.

8. The method of producing according to claim 1, wherein the step d) of thermal of treatment comprises an application of a temperature within a range of 400° C. and 1200° C. during, a period of time between a few hours and a few days.

9. The method of producing according to claim 1, wherein the method comprises prior to step d) of applying the thermal treatment, a step ii) including a deposition of at least one film of amorphous material on an exposed surface of the layer of amorphous SiyGe1-y.

10. The method of producing according to claim 9, wherein the step ii) including a deposition of at least one film of amorphous material on the exposed surface of the layer of amorphous Si_{y}Ge_{1-y} also includes a deposition of at least a film of the same amorphous material on a free surface of the seed film.

11. The method of producing according to claim 9, wherein the films of amorphous material comprise silicon oxide.

12. The method of producing according to claim 1, wherein the method comprises prior to step d) of applying the thermal treatment, a step iii) of additional thermal degassing treatment of the layer of amorphous Si_{y}Ge_{1-y}.

13. The method of producing according to claim 1, wherein x is equal to 1 and y is equal to 1 in such a manner that the substrate comprises at least on the surface a crystalline layer of silicon and that the step b) comprises the deposition of a layer of amorphous silicon on the seed film.

14. A weakened composite structure produced according to the process of claim 1, wherein the weakened composite structure comprises from its base to its surface, a substrate including at least on its surface a crystalline layer of SiₓGe₁₋ₓ having a weakened plane delimiting a seed film having a thickness between around 10 nanometers and 2 micrometers, a layer of amorphous Si_{y}Ge_{1-y} having a thickness higher than 10 micrometers on the seed film, the layer of amorphous Si_{y}Ge_{1-y} including a region of stress comprising implanted ionic species.

15. A detached structure produced according to the process of claim 1, wherein the detached structure comprises from its base to its surface, a film of amorphous material of silicon oxide having a thickness of a few dozen nanometers, a seed film of crystalline SiₓGe₁₋ₓ having a thickness between around 10 nanometers and 2 micrometers on the film of amorphous material, a layer of amorphous Si_{y}Ge_{1-y} having a thickness higher than 10 micrometers on the seed film and a film of amorphous material of silicon oxide having a thickness of a few dozen nanometers on the layer of amorphous Si_{y}Ge_{1-y}.
